(19) United States
(12) Patent Application Publication
(10) Pub. No.: US 2010/0139746 A1
(43) Pub. Date: Jun. 10, 2010

(54) SOLAR CELL DEVICE, SOLAR CELL MODULE, AND CONNECTOR DEVICE

(75) Inventors: Karsten Von Maydell, Potsdam (DE); Joerg Mueller, Sandersdorf (DE); Dominik Huljic, Leipzig (DE); Andreas Mohr, Leipzig (DE); Thomas Zerres, Koeln (DE); Sebastian Falkner, Leipzig (DE)

Correspondence Address: Workman Nydegger;1000 Eagle Gate Tower, 60 East South Temple, Salt Lake City, UT, 84111, US

(73) Assignee: Q-CELLS SE, Bitterfeld-Wolfen (DE)

(21) Appl. No.: 12/531,850

(22) PCT Filed: Mar. 13, 2008
(86) PCT No.: PCT/EP08/53011

§ 371 Date: Feb. 17, 2010

(30) Foreign Application Priority Data
Mar. 19, 2007 (DE) 10 2007 013 553.1

(51) Int. Cl. H01L 31/00

(52) U.S. Cl. 136/255

(57) ABSTRACT

A solar cell device includes a solar cell with a semiconductor having at least one p-doped region and at least one n-doped region. Electrical p-contacts and n-contacts on the back of the solar cell are connected to correspondingly doped regions of the semiconductor. At least one p-busbar is connected to the electrical p-contacts and at least one n-busbar is connected to the electrical n-contacts. The busbars collect current of the electrical contacts and form a direction of longitudinal extension and a connection arrangement providing an electrically conductive connection of at least one busbar of the solar cell to at least one busbar of an adjacent solar cell. The connection arrangement includes at least one first connection section extending essentially perpendicular to the direction of longitudinal extension of the busbars, which connection section, by way of connection regions, is connected in a point-like manner with at least one busbar.

### CROSS-REFERENCE TO A RELATED APPLICATION

This application is a National Phase Patent Application of International Patent Application Number PCT/EP 2008/053011, filed on Mar. 13, 2008, which claims priority of German Patent Application Number 10 2007 013 553.1, filed on Mar. 19, 2007.

### BACKGROUND

The invention relates to a solar cell device, to a solar cell module comprising such a solar cell device, and to a connection arrangement.

From US 2005/02 68 959 A1 a solar cell module is known in which the individual solar cells are interconnected by means of compact connection elements. Such compact connection elements can be used wherever there are no more than two busbars for each solar cell.

Gee et al. (“Simplified module assembly using back-contact crystalline-silicon solar cells”, 26^{th} IEEE PVSC, 1997, pp. 1085-1088) describe the interconnection of several solar cells in series, which interconnection takes place by means of a connection foil. In this arrangement the connection foil provides parallel alignment between contacts that are arranged on the foil and the contact regions of the solar cells to be interconnected.

De Jong et al. (“Single-step laminated full-size PV modules made with back-contacted mc-Si cells and conductive adhesives”, 19^{th} European Photovoltaic Solar Energy Conference, 2004, pp. 2145-2148) also propose series connection, integrated in foil, of back-contacted solar cells. In this arrangement the contact points of individual solar cells are connected in series, wherein a complex switching pattern is used.

Van Kershaver et al. (“Record high performance modules based on screen printed MWT solar cells”, 29^{th} IEEE PVSC, 2002, pp. 78-81) propose several switching modi of individual solar cells. In this arrangement switching is parallel to the busbars of the individual solar cells, wherein various geometric busbar arrangements are described in order to be able to interconnect solar cells comprising more than two busbars.

### SUMMARY

It is an object of the invention to create a back-contacted solar cell device which even if there are more than two busbars can easily be switched to other solar cells or solar cell devices to form a module. It is furthermore the object of the invention to create a corresponding solar cell module and a corresponding connection arrangement.

This object is met by a solar cell device which comprises a solar cell with a semiconductor that comprises at least one p-doped region and at least one n-doped region; with electrical p-contacts and electrical n-contacts that are arranged on the back of the solar cell and that are connected to the correspondingly doped regions of the semiconductor; with at least one p-busbar that is connected to the electrical p-contacts; and with at least one n-busbar that is connected to the electrical n-contacts; wherein the busbars in each instance collect the current of the electrical contacts and comprise a direction of longitudinal extension. Furthermore, a connection arrangement is provided which is designed to provide an electrically conductive connection of at least one of the busbars of the solar cell to at least one busbar of an adjacent solar cell.

In this context the term “back” designates the face of the solar cell device, which face is arranged opposite the front of the solar cell device, wherein incident light enters through the front of the solar cell.

A solar cell device according to an aspect of the invention is characterised in that the connection arrangement comprises at least one first connection section which extends so as to be essentially perpendicular to the direction of longitudinal extension of the busbars, which connection section, by way of connection regions, is connected in a point-like manner to at least one busbar. In this context the term “in a point-like manner” does not refer to a mathematical point but instead to a design of the connection region over a small surface area. In particular, the entire region of overlap of the first connection region with the corresponding busbar is considered to be a connection region over a small surface area.

In order to comprise a well-suited shape for contacting a further solar cell, the connection arrangement comprises in an embodiment at least one second connection section which just like the first connection section extends so as to be essentially perpendicular to the direction of longitudinal extension of the busbars of the solar cell, and furthermore comprises at least one third connection section that extends so as to be essentially parallel to the direction of longitudinal extension of the busbars. This means that the at least one first and the at least one second connection section in each instance extend parallel to each other and are arranged so as to be perpendicular relative to the at least one third connection section.

In order to achieve a fork-shaped design of the connection arrangement and thus achieve a particularly simple option of a serial interconnection of two or more solar cells, in an embodiment the first connection section is arranged on a first side of the third connection section of the connection arrangement, and the second connection section is arranged on a second side of the third connection section that is opposite the first side. This means that the second connection section is arranged on the third connection section rotated by approximately 180° relative to the first connection section. Thus the first and the second connection sections extend in directions that in each instance differ from that of the third connection section, while being aligned so as to be essentially parallel to each other.

In an embodiment, the first and the second connection sections are arranged on the third connection section in such a way that they are not aligned with each other. By means of this arrangement it is possible to arrange the connection arrangement on individual solar cells according to the invention in each instance at the same position while nevertheless being able to connect several solar cells in series to form a module, without having to make a change in orientation on the solar cells themselves or on the connection arrangements on the solar cells.

In order to contact a further solar cell the second connection section is in an embodiment intended and equipped to establish an electrically conductive connection with at least one busbar of an adjacent solar cell, wherein this busbar comprises, e.g., a polarity that is the opposite of the polarity of the busbar that is contacted by the first connection section of the connection arrangement.

This means that when the first connection section contacts an n-busbar of a solar cell, the second connection section is in an embodiment provided to contact a p-busbar of an adjacent solar cell. Accordingly the second connection section is in an embodiment provided to contact an n-busbar of an adjacent solar cell when the first connection section contacts a p-busbar of the solar cell. By means of this arrangement, serial connection of several solar cell devices is possible, wherein in each instance the n-busbars of the one solar cell are connected to the p-busbars of the other solar cell.

In order to keep the length of the electrical p-contacts and of the electrical n-contacts, which can for example be designed as contact fingers, as short as possible and in order to in this way achieve a well-suited current conduction by way of the busbars that are connected to the contacts, the solar cell comprises in an embodiment at least three busbars, wherein the first connection section of the connection arrangement interconnects at least two busbars of the solar cells, which busbars have the same polarity. As an alternative it is also possible for the first connection section to contact only a busbar of a specified polarity if in the case of three busbars there are not two identical busbars in this specified polarity in the solar cell.

With an equidistant space among the busbars being part of an embodiment, connection of several solar cells with three busbars is invariant compared to rotation of the individual solar cells by 180°. This facilitates series connection of the individual solar cells to form a solar cell module.

In order to achieve an electrically conductive connection between at least two busbars of the same polarity of the solar cell, the first connection section and/or the second connection section of the connection arrangement are/is in an embodiment dimensioned in such a way that they bridge at least one busbar which they do not contact.

This non-contacting busbar is in an embodiment a busbar with a polarity that is the opposite of the polarity of the busbars to be contacted.

In order to make it possible to affix the connection arrangement to the solar cell in a simple manner while at the same time ensuring adequate conductivity of the connection arrangement, the connection sections of the connection arrangement comprise in an embodiment a straight, elongated, rectangular shape.

In order to keep the resistance of the connection arrangement as low as possible, furthermore, in an embodiment of the invention in each instance several first, second and/or third connection sections are provided, which in each instance are arranged parallel to each other. In other words the several first connection sections are arranged parallel to each other, the several second connection sections are arranged parallel to each other, and the several third connection sections are arranged parallel to each other. The first and second or third connection sections can, however, be arranged so that they are not parallel to each other but instead, for example, perpendicular to each other.

In a further embodiment of the invention, in particular several parallel first connection sections and several second connection sections, which are arranged parallel to the former, as well as an individual third connection section that extends so as to be perpendicular to the first and the second connection sections, are provided.

In order to make possible more even current conduction away from the contacted busbars the several parallel connection sections are in an embodiment in each instance arranged so as to be equidistant from each other. In this arrangement the spaces between the first connection sections and the spaces between the second connection sections can differ.

In an embodiment of the invention, the connection arrangement comprises n first connection sections and n−1 second connection sections. This results in a fork-shaped structure of the connection arrangement that makes it possible to serially interconnect several solar cells that carry connection arrangements. In this arrangement in each instance the second connection sections engage the gaps that are formed between the first connection sections of a following solar cell device, so that the two second connection sections of a first solar cell device do not establish direct contact with the first connection sections of a second solar cell device.

In order to be able to optimally interact with a different number of contacting connection sections, the number of the connection regions for point-like contacting on the n-busbar differs in an embodiment from the number of the connection regions that are provided for point-like contacting on the p-busbar. In this arrangement, in particular, the number of connection regions on the respective busbar equals the number of the connection sections of the connection arrangement in order to contact the corresponding busbars.

To prevent the connection arrangement from generating a short circuit between the n-contacts and the p-contacts, but instead to ensure that said connection arrangement can only be connected in an electrically conductive manner by means of the busbars to be contacted, the connection arrangement is in an embodiment electrically insulated from the semiconductor outside the connection regions that are provided for point-like contact with the busbars. This can take place in that the connection arrangement itself comprises electrical insulation or in that the contact surface of the semiconductor of the solar cell comprises an electrical insulation layer. Moreover, the connection arrangement can be embedded in a foil that makes it possible to establish electrical contact in a point-like manner.

In order to make possible a space-saving arrangement of the connection arrangement on the semiconductor of the solar cell, the third connection section is in an embodiment directly located on one of the busbars of the solar cell. In this context, the term “on” denotes that the third connection section is directly arranged on the surface of the busbar. When the entire solar cell device is viewed, taking into account the fact that the solar cells according to the invention are back-contacted solar cells, the third connection section in this embodiment of the invention does in fact not rest on, but instead rests underneath a busbar of the solar cell.

In an arrangement of the third connection section of the connection arrangement on a busbar of the solar cell, the third connection section contacts in an embodiment in a point-like manner the busbar on which it is arranged. In this way a connection between the busbar to be contacted and the connection arrangement can be created that is not only implemented by means of the first connection section or sections or the second connection section or sections.

In an alternative embodiment of the invention, the third connection section is not arranged on a busbar of the solar cell, but instead adjacent to an edge region of the semiconductor or of the solar cell. In this case the third connection section is located beside the actual solar cell that comprises the semiconductor, the electrical p-contacts and the electrical n-contacts as well as the associated busbars.

In order to ensure good electrical conductivity between the electrical p-contacts and the electrical n-contacts with the correspondingly doped semiconductor regions, while at the same time achieving a high degree of design flexibility, the connection between the electrical contacts and the corresponding semiconductor regions is implemented in an embodiment by means of a point-shaped or a line-shaped contact region.

Since with an increase in the area of the solar cells, and thus with the associated increase in the current production as a result of conversion of incident light, the current that has to be conducted through the relatively narrow contacts or contact fingers increases too, it is necessary when maintaining the number of busbars to also increase the dimensions of the electrical contacts or contact fingers in order to avoid limiting the flow of current as a result of the resistance of the contacts. In order to avoid this problem, according to an embodiment of the invention a solar cell comprises more than two busbars. Said solar cell is thus, in particular, also suitable as a large-area solar cell with a high current production, which solar cell with more than two busbars, due to shortened electrical contacts, from the point of view of technology and cost, can be produced more economically than conventional solar cells.

In a further embodiment of the invention, a solar cell comprises two p-busbars and one n-busbar, or one n-busbar and two p-busbars.

An alternative embodiment of the invention provides for a solar cell to comprise two p-busbars and two n-busbars. Likewise, within the context of the present invention it is imaginable for a solar cell to comprise more than two p-busbars and/or more than two n-busbars.

In order to achieve a simple geometric design of a solar cell, in an embodiment the busbars of the solar cell are arranged so as to be essentially parallel to each other. This relates in particular to the direction of longitudinal extension of the busbars, wherein individual regions of the busbars, which regions do not have to have a strictly rectangular shape, may differ from a parallel arrangement.

The object of the invention is also met by a solar cell module with the characteristics of claim 23. Such a solar cell module comprises at least two solar cells according to claim 1.

In such an exemplary solar cell module each p-busbar or n-busbar of a first solar cell is connected in an electrically conductive way, by means of a connection arrangement, to each n-busbar or p-busbar of an adjacent solar cell. This results in a serial connection of several solar cells that form a solar cell module. By means of serial connection of individual solar cells to form a solar cell module, the quantity of the electrical current that is generated by conversion of incident light is increased.

For simple serial interconnection of several solar cells, the connection arrangement in a solar cell module comprises in an embodiment at least one first and one second connection section, which in each instance extends so as to be essentially perpendicular to the busbars of the individual solar cells, and comprises at least one third connection section, arranged between two solar cells, which extends so as to be essentially parallel to the busbars. This means that in this arrangement of the third connection section of the connection arrangement, a busbar of one of the solar cells that form the solar cell module is not directly contacted by the third connection section, but instead is contacted only by means of the first and/or the second connection section.

Furthermore, the object of the invention is also met by a connection arrangement for connecting two solar cells which comprises at least one first or one second connection section, which extend parallel to each other. Furthermore, there is at least one third connection section which extends so as to be essentially perpendicular to the first and to the second connection sections, wherein the first connection section is provided and designed for contacting a first solar cell, and the second connection section is provided and designed for contacting a second solar cell, which is arranged adjacent to the first solar cell. For example by means of a welding, soldering or bonding process, such a connection arrangement can be applied subsequently to an already existing solar cell in order to make it possible to electrically connect this solar cell to an adjacent solar cell. In particular, it is imaginable to produce the connection arrangement from a foil that provides electrical conductivity.

In an embodiment, the first connection section is arranged on a first side of the third connection section of the connection arrangement, and the second connection section is arranged on a second side of the third connection section, which second side is opposite the first side. This means that in each instance the first connection section and the second connection section are arranged on the third connection section of the connection arrangement with an orientation that differs by 180°. In this arrangement the first connection section and the second connection section extend in an embodiment so that they are parallel to each other.

In order to make possible an arrangement, at the same location, on solar cells that are connected in series, in an embodiment the first connection section and the second connection section are arranged in the third connection section of the connection arrangement in such a way that they are not aligned with each other. Thus in an easy manner a repetitive pattern of connection elements that are arranged at the same location on corresponding solar cells can be achieved without varying the relative orientation of the connection sections on the solar cells on which they are to be placed or have been placed. At the same time in this way a situation can be achieved in which the second connection section of a first connection arrangement does not establish electrical contact with the first connection section of a second connection arrangement, which second connection arrangement is arranged on a solar cell that is aligned adjacent to the solar cell on which the first connection section is arranged.

In order to use the connection arrangement for the electrically conductive connection of two solar cells that are to be interconnected, in an embodiment the first and/or the second connection section are/is provided and designed for contacting at least one busbar of the solar cell that is to be contacted in each instance. In this arrangement, in particular, the first connection section is provided for contacting a busbar of a first solar cell, and the second connection section is provided for contacting a busbar of a second solar cell. Instead of a busbar, in this arrangement it is also possible in each instance to contact and interconnect, on a solar cell, several busbars of the same polarity.

In order to keep the production of the connection arrangement as simple as possible and to achieve simple handling of the connection arrangement while at the same time achieving good electrical characteristics, the connection sections comprise in an embodiment a straight, elongated, rectangular shape.

In order to minimise the resistance and to ensure even current conduction away from the busbars of a, in particular, large-area solar cell, the connection arrangement in a embodiment of the invention in each instance comprises several parallel first, second and/or third connection sections; in other words the several first connection sections are in each instance arranged parallel to each other, just as the several second and the several third connection sections among themselves are in each instance arranged parallel to each other. The several first connection sections can, however, be arranged, for example, at right angles to the several third connection sections. In particular, it is provided for several first and several second connection sections and for a single third connection section to be provided.

In order to implement even current conduction away from the busbars in a well-suited manner, the several parallel connection sections are in an exemplary manner arranged so as to be equidistant from each other in each instance. In this arrangement the distances between the first connection sections can differ from the distances between the in each instance several second or if applicable in each instance several third connection sections.

In an embodiment of the invention, the connection arrangement comprises n first connection sections and n−1 second connection sections. In this way it is possible for the connection arrangement to be arranged, on solar cells to be contacted, in such a way that in each instance the second connection sections engage the gaps that are formed between the in each instance several first connection sections, so that the second connection sections of a first connection arrangement do not establish contact with the first connection section of a second connection arrangement when several solar cells, on which in each instance a connection arrangement is arranged, are connected in series.

In order to interact only with the busbars of solar cells to be contacted, while nevertheless preventing short circuits between the electrical n-contacts and electrical p-contacts of a semiconductor of a solar cell, the connection arrangement comprises in an embodiment electrical insulation at least in part. This electrical insulation is, in particular, interrupted only at the locations in which an electrical contact between the connection arrangement and a solar cell to be contacted is to be provided, in other words in particular in the region of a busbar of a solar cell, which busbar is to be contacted.

### BRIEF DESCRIPTION OF THE DRAWINGS

Further details of the invention are to be clarified with reference to the following figures.—

FIG. 1 shows a cross section of a solar cell;

FIG. 2 shows a view of the back of a solar cell;

FIG. 3 shows a rear view of a first switching arrangement of two solar cell devices to form a solar cell module;

FIG. 4 shows a cross section of a solar cell device;

FIG. 5 shows a rear view of a second switching arrangement of two solar cell devices to form a solar cell module; and

FIG. 6 shows a rear view of a third switching arrangement of two solar cell devices to form a solar cell module.

### DETAILED DESCRIPTION

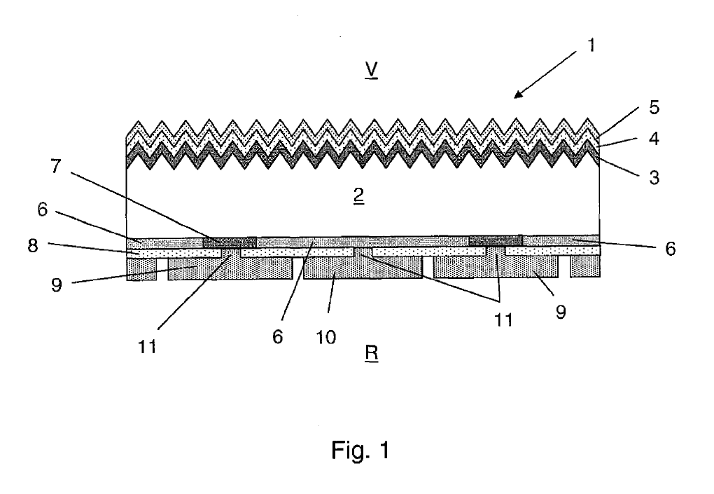

FIG. 1 shows a cross section of a solar cell 1 with a semiconductor 2 that comprises a textured semiconductor surface 3. Above the textured semiconductor surface 3 a first passivation layer 4 and an antireflection coating 5 are arranged. In this arrangement the textured semiconductor surface 3, the first passivation layer 4 and the antireflection coating 5 are located on the side that faces the light, in other words on the front V of the solar cell 1. The surface of the solar cell can also be designed in some other manner.

The side of the solar cell 1, which side is opposite the front V, is the side of the solar cell 1 which side faces away from the light, in other words the back R of said solar cell 1. In a lower region of the semiconductor 2, in other words on the region that faces the back R of the semiconductor 2, there is an alternating sequence, which extends parallel to the rear R, of diffusion regions of high p-doping 6 and diffusion regions of high n-doping 7. Underneath these diffusion regions 6, 7 the solar cell 1 comprises a dielectric second passivation layer 8, which prevents electrical contacting of the diffusion regions 6, 7 from the rear R.

On the side of the second passivation layer 8, which side faces the back R of the solar cell 1, the solar cell 1 comprises electrical n-contacts 9 and electrical p-contacts 10 which by way of openings 11 as contact apertures in the second passivation layer 8 are connected in an electrically conductive way with the corresponding p-doped diffusion regions 6 or n-doped diffusion regions 7. By way of these electrical n-contacts 9 and electrical p-contacts 10 a current that is produced by incident light on the solar cell can be conducted away. As a rule, the electrical contacts 9, 10 are designed as contact fingers, as is more clearly evident from the following drawings.

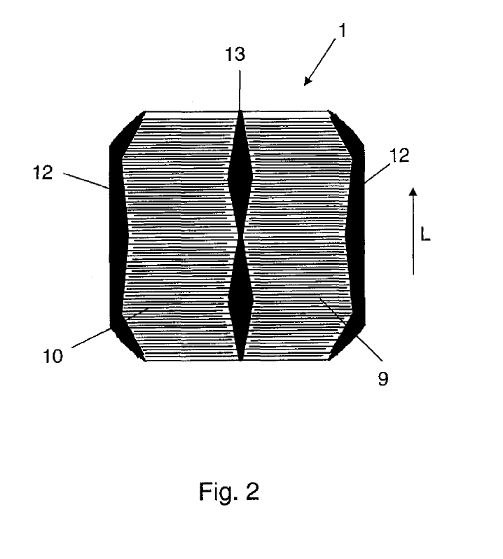

FIG. 2 shows a rear view of a solar cell 1 in which the finger-like structure of the electrical contacts 9, 10 is clearly shown. Thus the electrical contacts 9, 10 extend in an interdigitating manner to busbars that are arranged at the edge and in the middle of the solar cells.

Thus the solar cell 1 of FIG. 2 comprises two n-busbars 12, each being arranged at the edge of the solar cell 1. All the electrical n-contacts 9 of the solar cell 1 are connected to these n-busbars 12. In the middle of the solar cell 1a p-busbar 13 is arranged, by means of which the corresponding p-contacts 10 of the solar cell 1 are connected. The busbars 12, 13 comprise a direction L of longitudinal extension, which in the illustration of FIG. 2 extends from top to bottom or from bottom to top. In this arrangement the busbars 12, 13 are not strictly rectangular in shape. Instead, the p-busbar 13 is lozenge- or rhomb-shaped, while the n-busbars 12 at their ends are designed so as to be slightly angled. The busbars 12, 13 of the solar cell 1 are nevertheless aligned so as to be essentially parallel to each other. As an alternative, the busbars can also comprise some other elongated shape, for example they can be rectangular.

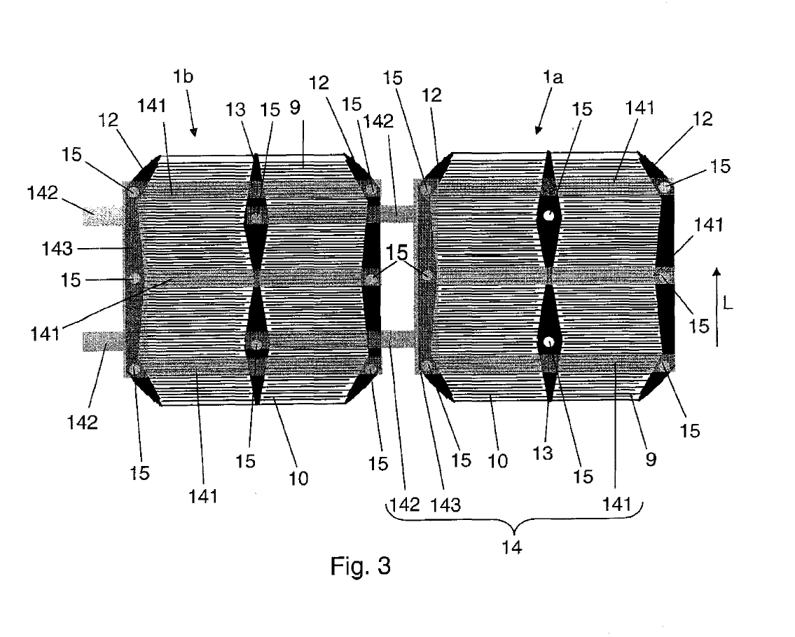

FIG. 3 shows a first exemplary embodiment of two solar cells 1a, 1b, which are interconnected to form a solar cell module. In this arrangement the solar cells 1a, 1b are shown in a rear view, as in FIG. 2, so that the finger-like electrical n- and p-contacts 9, 10 are shown. The n-busbars 12 of a first solar cell 1a, which are shown on the right-hand side in FIG. 3, are interconnected, by means of a connection arrangement 14, to the p-busbar 13 of a second solar cell 1b, which is shown on the left-hand side in FIG. 3.

In this arrangement the solar cells 1a, 1b, which are connected by means of the connection arrangement 14, can be designed according to FIGS. 1 and 2. However, solar cells that are designed in some other way can also be interconnected by means of the connection arrangement 14. This merely requires that both the emitter contact and the collector contact are designed on the back of the solar cell. The solar cells can, for example, also be designed as emitter-wrap-through solar cells.

The connection arrangement 14 comprises the form of a two-handled hay fork, which is achieved by arranging three first connection sections 141 that extend parallel to each other, a third connection section 143 that is arranged parallel to the former, and two second connection sections 142, which are arranged on the side of the third connection section 143, which side is opposite the side on which the first connection sections 141 are arranged on the third connection section 143.

In this arrangement the third connection section 143 of the connection arrangement 14 is arranged directly above one of the n-busbars of the first solar cell 1a and contacts it by means of three connection points 15. The first connection sections 141 also contact the second n-busbar 12 of the first solar cell 1a. In this way the two n-busbars 12 of the first solar cell 1a are electrically interconnected. In order to prevent any short circuit to the electrical contacts 9, 10 or to the p-busbar 13, the connection arrangement 14 is designed so as to be electrically insulated from the above-mentioned elements.

The second connection sections 142 of the connection arrangement 14 are in contact with the p-busbar 13 of the second solar cell 1b by way of connection points 15. This means that the connection arrangement 14 electrically interconnects the n-busbars 12 of the first solar cell 1a with the p-busbar 13 of the second solar cell 1b. In this way the first solar cell 1a and the second solar cell 1b are connected in series.

The connection arrangement 14 arranged on the underside of the busbars 12, 13 of the second solar cell 1b is connected to the n-busbars 12 of the second solar cell 1b, corresponding to the connection arrangement 14 of the first solar cell 1a, and serves to further connect the second solar cell 1b to the p-busbar of a further solar cell (not shown in FIG. 3).

The connection arrangement 14 provides an electrical connection of the first solar cell 1a to the second solar cell 1b, which extends so as to be essentially perpendicular to the direction of longitudinal extension L of the busbars 12, 13 of the two solar cells 1a, 1b.

Instead of the arrangement, shown in FIGS. 2 and 3, of two n-busbars 12 and one p-busbar 13 per solar cell 1, 1a, 1b, as an alternative it is also possible in each instance to provide only two p-busbars 13 and only one n-busbar 12.

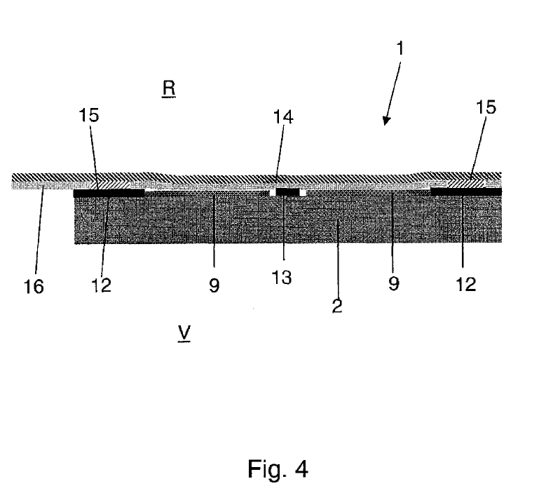

FIG. 4 shows a diagrammatic section view of a solar cell 1 with a connection arrangement, e.g. according to FIG. 3, in which the back R, which faces away from the light, of the solar cell 1 is arranged at the top, while the front V that faces the light is arranged at the bottom. Elements that have already been introduced have the same reference characters as in the already explained figures.

At the rear of the semiconductor 2, FIG. 4 shows the two n-busbars 12 that are arranged on the edge sides of the solar cell 1, as well as the p-busbar 13 that is arranged in the middle. In this arrangement the section through the solar cell 1 has been made at a position at which the n-busbars 12 are contacted by the finger-like electrical n-contacts 9. In order to prevent short circuiting, the electrical n-contacts 9 do not establish direct electrical contact with the p-busbar 13.

Above the busbars 12, 13, in other words on the face pointing towards the back R of the semiconductor 2, a dielectric insulation layer 16 has been applied to the busbars 12, 13 and to the electrical contacts 9, 10, which prevents undesirable contact between the busbars 12, 13 and the electrical contacts 9, 10 with elements that are arranged beyond the dielectric insulation layer 16. Directly on the insulation layer 16, the connection element 14 provides the rear finish of the solar cell 1, which connection element 14, by means of holes 15 in the insulation layer 16 which represent connection points, establishes electrical contact with the n-busbars 12 of the solar cell 1.

The cross section through the solar cell 1, which cross section is shown in FIG. 4, covers the region that is taken up by the first connection section 141 of the connection arrangement 14. In a section of a solar cell at a position at which the connection element 14 of an adjacent solar cell would contact the p-busbar 13 of the solar cell, a connection point 15 in the dielectric insulation layer 16 would correspondingly be designed in such a way that contact between the connection element 14 and the p-busbar 13 of the solar cell would be possible, but not an electrical connection between the n-busbar 12 and the connection element 14.

The insulation layer 16 can be arranged either directly underneath the connection element 14 on the back R of the solar cell 1, or it can be part of the connection element 14.

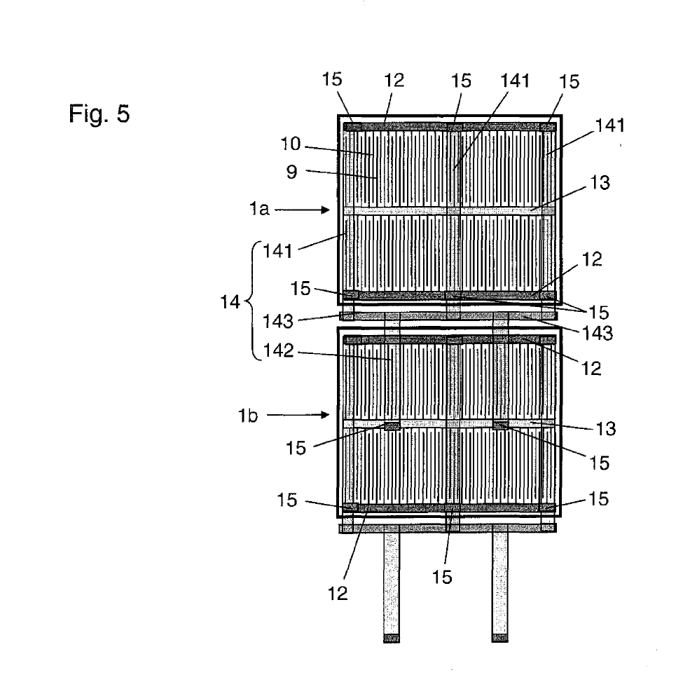

FIG. 5 shows a second exemplary embodiment of a connection of two solar cell devices to form a solar cell module. In this diagram elements that have already been introduced again have the known reference characters. There is a difference to the exemplary embodiment shown in FIG. 3 in that the third connection section 143 of the connection element 14 is not arranged on one of the n-busbars 12 of the solar cell 1a, 1b, but instead is located in a gap between the first solar cell 1a and the second solar cell 1b. Thus the third connection section 143 no longer directly contacts the n-busbar 12 of the first solar cell 1a; instead the three first connection sections 141, which extend parallel to each other, of the connection arrangement 14 equally contact both n-busbars 12 of the first solar cell 1a by way of contact points 15. These contact points 15 or connection regions for point-like contacting are provided in the regions in which the first connection sections 141 overlap the n-busbars. In this arrangement they do not necessarily fill the entire region of overlap, but instead can be restricted to a partial region of the overlapping region between the first connection sections 141 and the n-busbars 12.

The number of contact points 15 corresponds to the number of connection sections 141, 142, 143 that are contacted by the corresponding connection element 14. In this arrangement the number of contact points 15 on the n-busbars 12 differs from the number of contact points on the p-busbars, which is reflected in an asymmetrical design of the connection element 14.

In each instance the first connection sections 141 comprise a length that makes it possible for them to contact both n-busbars 12 that are arranged at the edge regions of the first solar cell 1a and at the same time to bridge the p-busbar 13 that is arranged in the middle, without contacting said p-busbar 13. As far as the necessary insulation between the connection arrangement 14 and the electrical contacts 9, 10 and the busbar 13 of the solar cell 1a, which busbar 13 is not to be contacted, is concerned, reference is made to the illustration of FIG. 4.

The second connection sections 142, too, which like the first connection sections 141 are connected to the third connection section 143 of the connection arrangement 14, bridge the n-busbar 12 of the second solar cell 1b, which n-busbar 12 is not to be contacted, in order to subsequently at connection points 15 contact the p-busbar 13 of the second solar cell 1b. The contact points 15 between the two second connection elements 142 and the p-busbar 13 of the second solar cell 1b, which connection elements 142 are arranged so as to be parallel to each other, are designed so as to be equivalent to the connection points 15 between the first connection sections 141 and the n-busbars 12 of the first solar cell 1a.

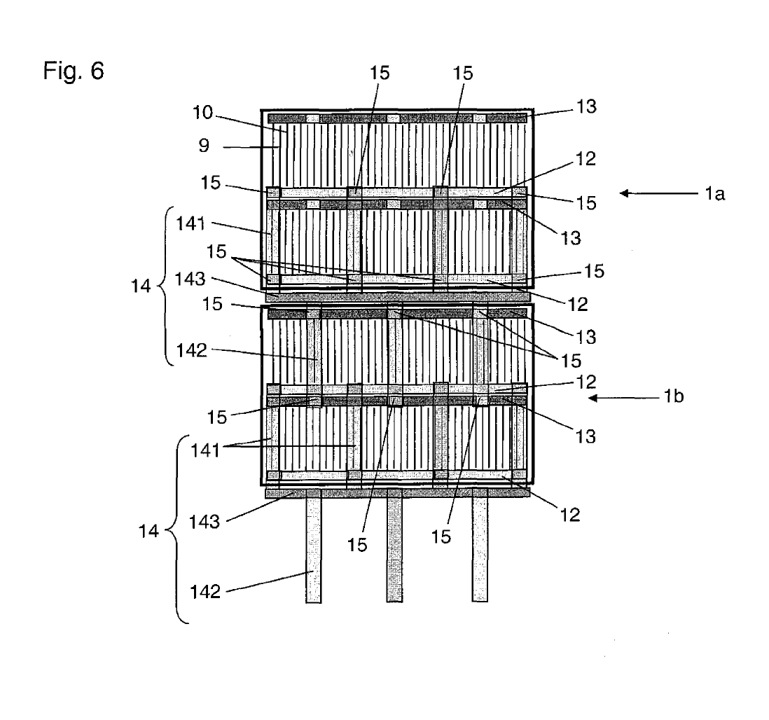

FIG. 6 shows a third exemplary embodiment of a connection arrangement between two solar cell devices and a solar cell module. In contrast to the exemplary embodiments shown in FIGS. 3 and 5, the first solar cell 1a and the second solar cell 1b of the arrangement shown in FIG. 6 in each instance comprise two n-busbars 12 and two p-busbars 13. In this embodiment the connection elements 14 comprise four first sections 141 and three second sections 142 as well as a third section 143. This is, in particular, due to the somewhat wider design of the solar cells. Likewise, it would be imaginable, as is the case in the preceding exemplary embodiments, to use three first connection sections 141 and two second connection sections 142 or to provide some other number of connection sections.

The first connection sections 141 contact the two n-busbars 12 of the first solar cell 1a, thus bridging in a contactless manner one of the two p-busbars 13 of the first solar cell 1a. The three second connection sections 142 of the connection arrangement 14 furthermore contact the two p-busbars 13 of the second solar cell 1b and in so doing bridge one of the two n-busbars of the second solar cell 1b in a contactless manner. Contacting the first or second connection sections 141, 142 and the corresponding busbars 12, 13 takes place in a point-like manner by way of contact points 15.

The third connection section 143, on whose first side the first connection sections 141, and on whose second side, which is opposite the first side, the second connection sections 142 are arranged, which third connection section 143 thus connects the first connection sections 141 to the second connection sections 142, is arranged between the two solar cells 1a and 1b, as is also the case in the exemplary embodiment of FIG. 5. This means that in the exemplary embodiment of FIG. 6, too, the third connection section 143 does not directly contact a busbar 12, 13 of one of the two solar cells 1a, 1b.

The second connection sections 142 are arranged on the third connection section 143 in such a way that they are not aligned with the first connection sections 141, but instead are arranged in a middle position between two first connection sections 141. As a result of this they can be inserted into the gap that is present between two first connection sections 141 of the connection arrangement 14 on the second solar cell 1b. Thus the second connection sections 142 of the connection arrangement 14 of the first solar cell 1a do not contact the first connection sections 141 of the connection arrangement 14 of the second solar cell 1b, even if such a contact would be possible due to the longitudinal extension of the first connection sections 141 or of the second connection sections 142.

Consequently, as a result of the offset arrangement of the first connection sections 141 and of the second connection sections 142 on the third connection section 143, a repetitive arrangement of interconnected solar cells, which in each instance carry a connection element 14, is possible. This not only applies to the exemplary embodiment shown in FIG. 6, but also to the other exemplary embodiments of the invention.

1-35. (canceled)

36. A solar cell device comprising a solar cell with
a semiconductor that comprises at least one p-doped region and at least one n-doped region;
electrical p-contacts and electrical n-contacts that are arranged on the back of the solar cell and that are connected to the correspondingly doped regions of the semiconductor; and
at least one p-busbar that is connected to the electrical p-contacts; and at least one n-busbar that is connected to the electrical n-contacts, wherein the busbars in each instance collect the current of the electrical contacts and comprise a direction of longitudinal extension;
as well as a connection arrangement which is designed to provide an electrically conductive connection of at least one of the busbars of the solar cell to at least one busbar of an adjacent solar cell, wherein the connection arrangement comprises at least one first connection section which extends so as to be essentially perpendicular to the direction of longitudinal extension of the busbars, which connection section, by way of connection regions, is connected in a point-like manner with at least one busbar.

37. The solar cell device according to claim 36, wherein the connection arrangement comprises at least one second connection section which extends so as to be essentially perpendicular to the direction of longitudinal extension of the busbars, and at least one third connection section that extends so as to be essentially parallel to the direction of longitudinal extension of the busbars.

38. The solar cell device according to claim 37, wherein the first connection section is arranged on a first side of the third connection section, and the second connection section is arranged on a second side, which is opposite the first side, of the third connection section.

39. The solar cell device according to claim 37, wherein the second connection section is intended and equipped to contact at least one busbar of an adjacent solar cell, wherein this busbar comprises a polarity that is the opposite of the polarity of the busbar that is contacted by the first connection section.

40. The solar cell device according to claim 36, wherein the solar cell comprises at least three busbars, and the first connection section interconnects at least two busbars of the solar cell, which busbars have the same polarity.

41. The solar cell device according to claim 36, wherein the first connection section and/or the second connection section are/is of such a length that the first connection section and/or the second connection section bridge/bridges at least one busbar which they do not contact.

42. The solar cell device according to claim 36, wherein the number of the connection regions for point-like contacting on the n-busbar differs from the number of the connection regions that are provided for point-like contacting on the p-busbar.

43. The solar cell device according to claim 37, wherein the third connection section is arranged adjacent to an edge region of the solar cell.

44. The solar cell device according to claim 36, having two p-busbars and one n-busbar or vice versa.

45. The solar cell device according to claim 36, having two p-busbars and two n-busbars.

46. A solar cell module comprising at least two solar cell devices according to claim 36.

47. A connection arrangement for connecting two solar cells according to claim 36, wherein the connection arrangement comprises at least one first and one second connection section which extend so as to be parallel to each other, and comprises at least one third connection section which extends so as to be essentially perpendicular to the first and the second connection sections, wherein the first connection section is provided and equipped to contact a first solar cell, and the second connection section is provided and equipped to contact a second solar cell that is arranged adjacent to the first solar cell.

48. The connection arrangement according to claim 47, wherein the first connection section is arranged on a first side of the third connection section, and the second connection section is arranged on a second side of the third connection section, which second side is opposite the first side.

49. The connection arrangement according to claim 47, wherein the first and the second connection sections are arranged on the third connection section in such a way that they are not aligned with each other.

50. The connection arrangement of claim 47, wherein the connection sections are integrated in a foil.
